(19) United States
(12) Patent Application Publication
(10) Pub. No.: US 2005/0087835 A1
(43) Pub. Date: Apr. 28, 2005

(54) Semiconductor device and manufacturing method of the same

(76) Inventors: Masahiro Hayashi, Sakata-shi (JP); Takafumi Noda, Shiojiri-shi (JP); Yoshinobu Yusa, Sakata-shi (JP)

Correspondence Address: EDWARDS & ANGELL, LLP, P.O. BOX 55874, BOSTON, MA, 02205, US

(21) Appl. No.: 10/961,769

(22) Filed: Oct. 7, 2004

(30) Foreign Application Priority Data
Oct. 7, 2003 (JP) 2003-348381

(51) Int. Cl. H01L 29/00

(52) U.S. Cl. 257/509; 257/647; 438/225; 438/297

(57) ABSTRACT

A semiconductor device of the present invention is provided with a high breakdown voltage transistor 100 and a low voltage driving transistor 200 on a same semiconductor layer 10 comprising:
the semiconductor layer 10;
an offset insulating layer 20 comprising a LOCOS layer for an electric field relaxation of the high breakdown voltage transistor 100 provided on the semiconductor layer 10; and
a trench insulating layer 28 for defining a forming region of the low voltage driving transistor 200 provided on the semiconductor layer 10,
wherein at least a part of the upper surface of the offset insulating layer 20 is nearly as high as the surface of the semiconductor layer 10.

The present invention claim priority from Japanese Application No. 2003-348381 filed on Oct. 7, 2003, which is hereby incorporated by reference in its entirety.

### BACKGROUND OF THE INVENTION

1. Field of the Invention

The present invention relates to a semiconductor device provided with MOS transistors (Metal Oxide Semiconductor) having different drain breakdown voltages on a same semiconductor layer and a manufacturing method of the same.

2. Related Art

At present, there is a field effect transistor having a LOCOS (Local Oxidation Of Silicon) offset structure as the field effect transistor in which a high breakdown voltage is attained. The field effect transistor having the LOCOS offset structure is a transistor in which a LOCOS layer is provided between a gate insulating layer and a drain region, and an offset impurity layer is formed under the LOCOS layer.

Furthermore, with recent reduction in weight and size of various kinds of electronic equipment, miniaturization of an IC mounted on the electronic equipment is requested. In particular, for electronic equipment mounted to a liquid crystal display device, a technology has been strongly desired, in which a low voltage driving transistor for a low voltage operation and a high breakdown voltage transistor for a high voltage operation to the IC for driving are mounted on a same substrate (same chip) and miniaturizing the IC chip area. In the case when forming the high breakdown voltage transistor provided with the LOCOS layer for an electric field relaxation as described above and the low voltage driving transistor on the same substrate, for example, the LOCOS layer for the an element isolation and the LOCOS layer for the electric field relaxation are formed in the same process.

However, with recent requests to miniaturize the semiconductor device, a forming method of an element isolating region is transitioning from a LOCOS method to an STI (Shallow Trench Isolation) method, and a method has been proposed which also substitutes the LOCOS layer of the high breakdown voltage transistor for the electric field relaxation with a trench insulating layer formed by the STI method. In this way, in the case when forming the LOCOS layer for the electric field relaxation with the trench insulating layer, the following phenomena may happen. For a gate insulating layer of the high breakdown voltage transistor, the gate insulating layer whose film is thick is used to ensure the breakdown voltage. In the case when forming the gate insulating layer whose film is thick on an offset layer composed of the trench insulating layer, there may occur a phenomenon called thinning, in which the film thickness of the gate insulating layer formed on the upper end portion of the trench insulating layer becomes thin. The thinning occurs in this way, then the gate insulating layer of uniform film thickness becomes difficult to form, which may affect on reliability of the semiconductor device. The objective of the present invention is to provide a semiconductor device in which the high breakdown voltage transistor and the low voltage driving transistor are formed on the same substrate, which is capable of miniaturizing and improving reliability by using the LOCOS layer and the trench insulating layer simultaneously, and a manufacturing method of the same.

### SUMMARY OF THE INVENTION

A semiconductor device according to one embodiment of the present invention in which a high breakdown voltage transistor and a low voltage driving transistor are formed on a same semiconductor layer comprises,
the semiconductor layer,
an offset insulating layer composed of a LOCOS layer or a semi-recessed LOCOS layer for an electric field relaxation of the high breakdown voltage transistor provided on the semiconductor layer, and
a trench insulating layer for defining a forming region of the low voltage driving transistor provided on the semiconductor layer,
wherein at least a part of the upper surface of the offset insulating layer is nearly as high as the surface of the semiconductor layer.

According to the semiconductor device of one embodiment of the present invention, at least a part of the upper surface of the LOCOS layer or the semi-recessed LOCOS layer which is the offset insulating layer of the high breakdown voltage transistor is nearly as high as the surface of the semiconductor layer. The LOCOS layer or the semi-recessed LOCOS layer is formed by a selective thermal oxidation method, therefore, the upper surface is formed to rise above the surface of the semiconductor layer. Accordingly, there occurs difference of elevation in the surface of the semiconductor layer. In the case when providing the LOCOS layer or the semi-recessed LOCOS layer and the trench insulating layer on the same semiconductor layer, the trench insulating layer is formed after the LOCOS layer or the semi-recessed LOCOS layer is formed, in order to prevent the trench insulating layer from being stressed, for example, due to exposition to heat treatment when the LOCOS layer or the semi-recessed LOCOS layer is formed. At this time, if there remains difference of elevation in the surface of the semiconductor layer, a CMP process after an insulating layer is embedded in the trench cannot be acceptably carried out and sufficient flattening cannot be performed. However, in the semiconductor device of at least one embodiment of the present invention, at least a part of the upper surface of the LOCOS layer or the semi-recessed LOCOS layer is nearly as high as the surface of the semiconductor layer, therefore, flatness in the surface can be improved. Therefore, the difference of elevation is an extent that does not affect the flattening process such as a CMP. As a result, a semiconductor device with high reliability can be provided.

Furthermore, the semiconductor device of one embodiment of the present invention can have the following aspect.

The entire surface of the upper surface of the offset insulating layer can be nearly as high as the surface of the semiconductor layer.

The semiconductor layer can be provided with a guard ring surrounding a forming region of the high breakdown voltage transistor. According to this aspect, there is a following advantage. For example, in the case when the LOCOS layer is used to define the forming region of the high breakdown voltage transistor, the upper surface of the LOCOS layer is nearly as high as the surface of the semiconductor layer, therefore, at least a part is removed. For this reason, sufficient breakdown voltage may not be secured. However, according to this aspect, such a problem can be avoided by carrying out an element isolation of the high breakdown voltage transistor with the guard ring.

(C) The semiconductor layer can be provided with the LOCOS layer or the semi-recessed LOCOS layer as the element isolation for defining the forming region of the high breakdown voltage transistor.

(D) The semiconductor layer can be provided with the trench insulating layer as the element isolation for defining the forming region of the high breakdown voltage transistor.
2. The manufacturing method of the semiconductor device
2-1. The manufacturing method of one embodiment of the semiconductor device according to the present invention comprises:
   (a) forming the LOCOS layer or the semi-recessed LOCOS layer on the semiconductor layer;
   (b) etching at least a part of the upper surface of the LOCOS layer or the semi-recessed LOCOS layer, and;
   (c) forming the trench insulating layer on the semiconductor layer.

According to the manufacturing method of one embodiment of the semiconductor device of the present invention, after at least a part of the upper surface of the LOCOS layer or the semi-recessed LOCOS layer formed on the semiconductor layer is etched, the trench insulating layer is formed. In general, the LOCOS layer is formed by using the selective thermal oxidation method, therefore, it is formed to rise above the surface of the substrate. In this way, when the CMP process required when forming the trench insulating layer is carried out with a difference of elevation on the surface of the substrate, a difference in an etching rate occurs and then the CMP (flattening) cannot be acceptably carried out. However, according to the manufacturing method of one embodiment of the semiconductor device of the present invention, after the LOCOS layer or the semi-recessed LOCOS layer is formed, at least a part of the upper surface of the LOCOS layer or the semi-recessed LOCOS layer is etched, therefore, the difference of elevation on the surface of the semiconductor layer can be decreased. For this reason, the CMP can be favorably carried out when the trench insulating layer is formed. As a result, even for the semiconductor device using a combination of the trench insulating layer and the LOCOS layer or the semi-recessed LOCOS layer, the semiconductor device having acceptable performance can be manufactured.
2-2. The manufacturing method of another embodiment of the semiconductor device according to the present invention comprises,
   (a) forming the LOCOS layer or the semi-recessed LOCOS layer for the electric field relaxation of the high breakdown voltage transistor on the semiconductor layer,
   (b) removing at least a part of the upper surface of the LOCOS layer or the semi-recessed LOCOS layer, and forming the offset insulating layer, and,
   (c) forming the trench insulating layer for defining the forming region of the low voltage driving transistor on the semiconductor layer.

According to this manufacturing method, after at least a part of the upper surface of the LOCOS layer or the semi-recessed LOCOS layer for the electric field relaxation of the high breakdown voltage transistor formed on the semiconductor layer is etched, the trench insulating layer for defining the low voltage driving transistor region is formed. In general, the LOCOS layer or the semi-recessed LOCOS layer is formed by using the selective thermal oxidation method, therefore, it is formed to rise above the surface of the substrate. In this way, if the CMP process required when forming the trench insulating layer carried out with a difference of elevation on the surface of the substrate, a difference in the etching rate occurs, therefore the CMP (flattening) cannot be favorably carried out. However, according to the manufacturing method of one embodiment of the semiconductor device of the present invention, after the LOCOS layer or the semi-recessed LOCOS layer is formed, at least a part of the upper surface of the LOCOS layer or the semi-recessed LOCOS layer is etched, therefore, the difference of elevation on the surface of the semiconductor layer can be decreased. For this reason, the CMP can be favorably carried out when the trench insulating layer is formed. As a result, the semiconductor device using a combination of the trench insulating layer and the LOCOS layer or the semi-recessed LOCOS layer can be manufactured, thereby the semiconductor device having favorable performance can be manufactured.

Furthermore, the manufacturing method of the semiconductor device of the present invention can have the following aspect.

(A) In the manufacturing method of the semiconductor device of the present invention, step (a) can include:
(a-1) forming an oxidation resistant film on the semiconductor layer,
(a-2) removing the oxidation resistant film in the forming region of the LOCOS layer or the semi-recessed LOCOS layer, and
(a-3) forming the LOCOS layer or the semi-recessed LOCOS layer by performing a thermal oxidation by using the oxidation resistant film as a mask,
wherein, the (b) includes etching the upper surface of the LOCOS layer or the semi-recessed LOCOS layer by using the remaining oxidation resistant film as the mask.

(B) In the manufacturing method of the semiconductor device of the present invention, the (a) includes,
(a-1) forming the oxidation resistant film on the semiconductor layer,
(a-2) removing the oxidation resistant film in the forming region of the LOCOS layer or the semi-recessed LOCOS layer, and
(a-3) forming the LOCOS layer or the semi-recessed LOCOS layer by performing the thermal oxidation by using the oxidation resistant film as the mask,
   and further, removing the remaining oxidation resistant film before the (b).

(C) In the manufacturing method of the semiconductor device of the present invention, the (c) includes,
(c-1) forming a trench on the semiconductor layer,
(c-2) forming the insulating layer above the semiconductor layer where the trench is formed, and
(c-3) flattening the insulating layer by the CMP method.

(D) In the manufacturing method of the semiconductor device of the present invention, the etching in the (b) can be carried out by isotropic etching.

### BRIEF DESCRIPTION OF THE DRAWINGS

FIG. 1 is a cross sectional view schematically showing a semiconductor device of the present embodiment.

FIG. 2 is a cross sectional view schematically showing one process of the manufacturing method of the semiconductor device of the present embodiment.

FIG. 3 is a cross sectional view schematically showing one process of the manufacturing method of the semiconductor device of the present embodiment.

FIG. 4 is a cross sectional view schematically showing one process of the manufacturing method of the semiconductor device of the present embodiment.

FIG. 5 is a cross sectional view schematically showing one process of the manufacturing method of the semiconductor device of the present embodiment.

FIG. 6 is a cross sectional view schematically showing one process of the manufacturing method of the semiconductor device of the present embodiment.

FIG. 7 is a cross sectional view schematically showing one process of the manufacturing method of the semiconductor device of the present embodiment.

FIG. 8 is a cross sectional view schematically showing one process of the manufacturing method of the semiconductor device of the present embodiment.

FIG. 9 is a cross sectional view schematically showing one process of the manufacturing method of the semiconductor device of the present embodiment.

FIG. 10 is a cross sectional view schematically showing one process of the manufacturing method of the semiconductor device of the present embodiment.

FIG. 11 is a cross sectional view schematically showing one process of the manufacturing method of the semiconductor device of the present embodiment.

FIG. 12 is a cross sectional view schematically showing one process of the manufacturing method of the semiconductor device of the present embodiment.

FIG. 13 is a cross sectional view schematically showing one process of the manufacturing method of the semiconductor device of the present embodiment.

FIG. 14 is a cross sectional view schematically showing one process of the manufacturing method of the semiconductor device of the present embodiment.

FIG. 15 is a cross sectional view schematically showing one process of the manufacturing method of the semiconductor device of the present embodiment.

FIG. 16 is a cross sectional view schematically showing one process of the manufacturing method of the semiconductor device of the present embodiment.

FIG. 17 is a cross sectional view schematically showing one process of the manufacturing method of the semiconductor device of the present embodiment.

FIG. 18 is a cross sectional view schematically showing one process of the manufacturing method of the semiconductor device of the present embodiment.

FIG. 19 is a cross sectional view schematically showing one process of the manufacturing method of the semiconductor device of the present embodiment.

FIG. 20 is a cross sectional view schematically showing one process of the manufacturing method of the semiconductor device of the present embodiment.

FIG. 21 is a cross sectional view schematically showing one process of the manufacturing method of the semiconductor device of the present embodiment.

FIG. 22 is a cross sectional view schematically showing one process of the manufacturing method of the semiconductor device of the present embodiment.

FIG. 23 is a cross sectional view schematically showing one process of the manufacturing method of the semiconductor device according to the present modification.

FIG. 24 is a cross sectional view for explaining advantage of the manufacturing method of the semiconductor device according to the present modification.

### DESRIPTION OF THE PREFERRED EMBODIMENTS

Next, an example of embodiments of the present invention will be described.

1. Semiconductor Device

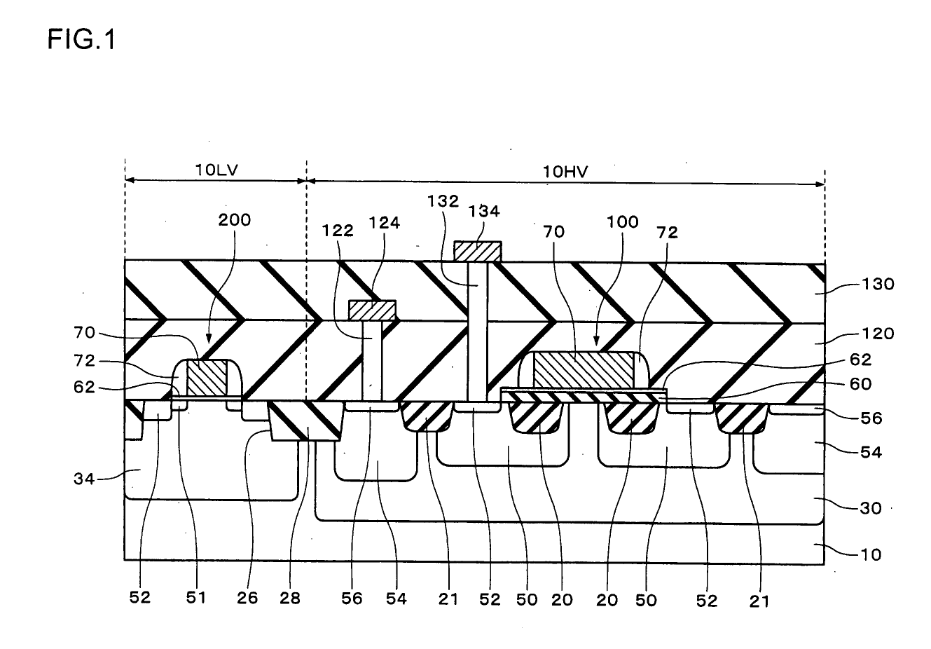

FIG. 1 is a cross sectional view schematically showing a semiconductor device of the present embodiment. In the semiconductor device of the present embodiment, a P-channel high breakdown voltage transistor 100 and a P-channel low voltage driving transistor 200 are mounted on the same semiconductor substrate 10 which is a semiconductor layer. A high breakdown voltage transistor region 10HV and a low voltage driving transistor region 10LV are provided in the semiconductor substrate 10. In addition, only two transistors are described in FIG. 1, however, they are conveniently described, and it is unnecessary to say that a plurality of various kinds of transistors are formed on the same substrate. Furthermore, a “LOCOS layer” referred in the following description simply means an insulating layer formed on the a semiconductor substrate 10 by a selective thermal oxidation method, including a semi-recessed LOCOS layer.

1.1 High Breakdown Voltage Transistor Region

First, the high breakdown voltage transistor region 10HV will be described. As described above, the high breakdown voltage transistor region 10HV is provided with the high breakdown voltage transistor 100.

The high breakdown voltage transistor 100 has a gate insulating layer 60, an offset insulating layer 20, a gate electrode 70, a P-type low concentration impurity layer 50, a sidewall insulating layer 72, and a P-type high concentration impurity layer 52. The offset insulating layer 20 is composed of the semi-recessed LOCOS layer, and is formed so that the upper surface thereof is nearly as high as the surface of the semiconductor substrate 10. Now, being “nearly as high” as means that it is sufficient that there is a difference of elevation in an extent where a CMP process carried out during the manufacturing process of the semiconductor device according to the present embodiment is acceptably carried out.

The gate insulating layer 60 is a multi layered film of a gate insulating 60a whose film is thick and a gate insulating layer 62 for the low voltage drive transistor 200, and is formed so as to cover an N-type well 30 which is a channel region, the offset insulating layer 20 and a semiconductor layer 10 on both sides of the offset insulating layer 20. The gate electrode 70 is formed on the gate insulating layer 60. The P-type low concentration impurity layer 50 becomes an offset region. The sidewall insulating layer 72 is formed on the side surface of the gate electrode 70. The P-type high concentration impurity layer 52 becomes a source region or a drain region (hereinafter, referred to as “source/drain region”).

The high breakdown voltage transistor 100 is provided with a guard ring region 56 comprising a high concentration impurity layer so as to surround the outside of a P-type high concentration impurity layer 52 which is the source/drain region. The N-type low concentration impurity layer 54 with lower concentration than the impurity layer constituting a guard ring region 56 is provided below the guard ring region 56. The guard ring region 56 and the high concentration impurity layer 52 which is the source/drain region are isolated by the isolation insulating layer 21.

1.2 Low Voltage Driving Transistor Region

Next, a low voltage driving transistor region 10LV will be described. The low voltage driving transistor region 10LV is defined by an element isolation region 210 comprising a trench insulating layer 28 formed by an STI method. The low voltage driving transistor region 10LV is provided with a P-channel low voltage driving transistor 200.

The low voltage driving transistor 200 has the gate insulating layer 62, the gate electrode 70, the sidewall insulating layer 72, the P-type low concentration impurity layer 51 and the P-type high concentration impurity layer 52.

The gate insulating layer 62 is provided on an N-type well 34 which becomes a channel region. The gate electrode 70 is formed on the gate insulating layer 62. The sidewall insulating layer 72 is formed on the side surface of the gate electrode 70. The P-type low concentration impurity layer 51 and the P-type high concentration impurity layer 52 constitute the source/drain region having a LDD structure.

Interlayer insulating layers 120 and 130 are deposited above the high breakdown voltage transistor 100 and the low voltage driving transistor 200. A wiring layer 134 to which high potential is given is provided above the interlayer insulating layer 130. The wiring layer 134 and the source/drain region 52 are electrically coupled through a contact layer 132. Further, a wiring layer 124 in which potential is fixed is provided above the interlayer insulating layer 120. The wiring layer 124 and the guard ring region 56 are electrically coupled through the contact layer 124.

According to the semiconductor device of the present embodiment, the offset insulating layer 20 in the high breakdown voltage transistor 100 comprises the semi-recessed LOCOS layer which is nearly as high as the surface of the semiconductor substrate 10. In general, the upper surface of the LOCOS layer is formed to rise above the surface of the semiconductor substrate 10, therefore, there occurs difference of elevation in the surface of the semiconductor substrate 10. In the case when providing the LOCOS layer and the trench insulating layer on the same semiconductor layer 10, the trench insulating layer is formed after the LOCOS layer is formed in order to prevent the trench insulating layer from being stressed, due to exposition of the trench insulating layer to atmosphere of the thermal oxidation required when the LOCOS is formed. And, a difference of elevation has occurred in the surface of the semiconductor substrate 10 after the LOCOS layer is formed, therefore, the CMP process after the insulating layer is embedded in the trench cannot be favorably carried out and sufficient flattening cannot be performed. However, in the semiconductor device of the present embodiment, the offset insulating layer 20 comprises the semi-recessed LOCOS layer whose at least a part of the upper surface is nearly as high as the surface of the semiconductor substrate 10, therefore, flatness in the surface can be improved. As a result, according to the semiconductor device of the present invention, the semiconductor device with high reliability can be provided.

Furthermore, the element isolation region 210 of the low voltage driving transistor forming region 10LV is carried out by the trench insulating layer 28, and then semiconductor device can be also miniaturized.

2. The Manufacturing Method of the Semiconductor Device

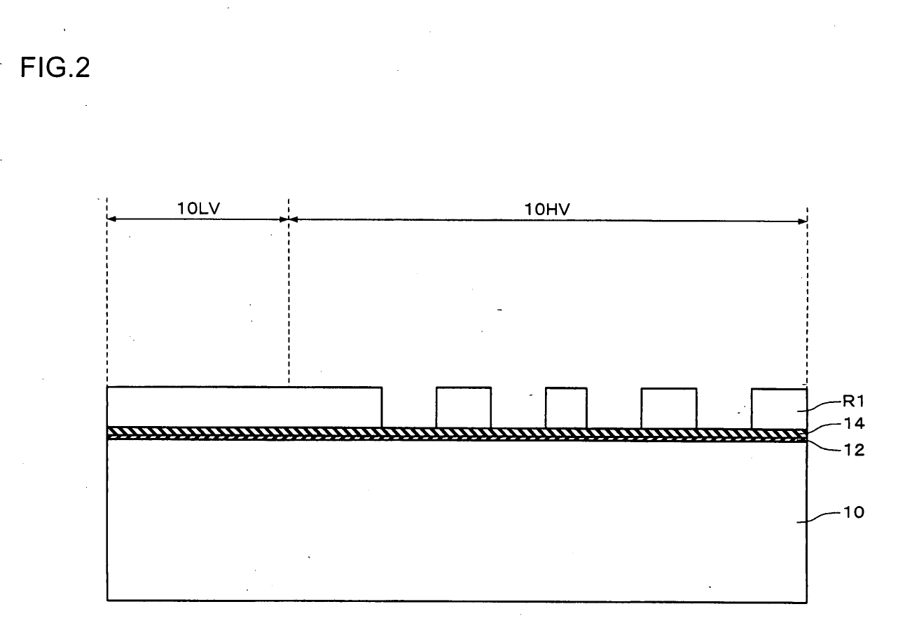

Next, the manufacturing method of the semiconductor device according to the present embodiment will be described with reference to FIG. 2 through FIG. 22. FIG. 2 through FIG. 22 are cross sectional views schematically showing processes of the manufacturing method of the semiconductor device according to the present embodiment.

(1) First, as shown in FIG. 2, in a high breakdown voltage transistor forming region 10HV, the offset insulating layer 20 for the electric field relaxation and the isolation insulating layer 21 (see FIG. 2) for isolating the region where the guard ring is formed, are formed.

First, an oxidation silicon nitride layer 12 is formed by a CVD method on the semiconductor substrate 10. The film thickness 12 of the oxidation silicon nitride layer is, for example, 8 through 12 nm. Next, a silicon nitride layer 14 playing a role of an oxidation resistant film is formed on the oxidation silicon nitride layer 12 by the CVD method. Then, a resist layer R1 (mask layer) having an opening to a region where the offset insulating layer 20 and the isolation insulating layer 21 are formed, is formed on the silicon nitride layer 14.

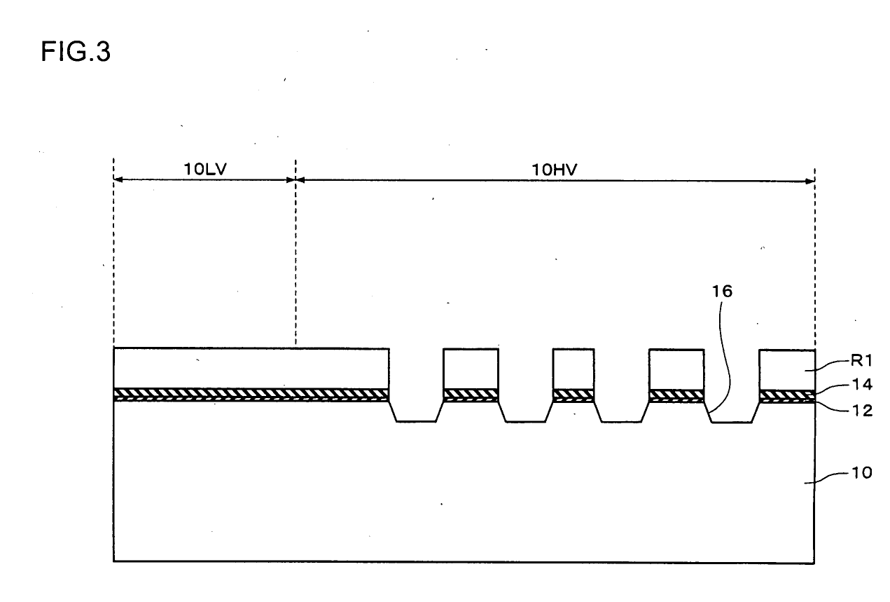

(2) Next, as shown in FIG. 3, using this resist layer R1 as a mask, the silicon nitride layer 14, the oxidation silicon nitride layer 12 and the semiconductor substrate 10 are etched. This allows a grooved portion 16 to be formed on the semiconductor substrate 10. Next, the resist layer R1 is removed.

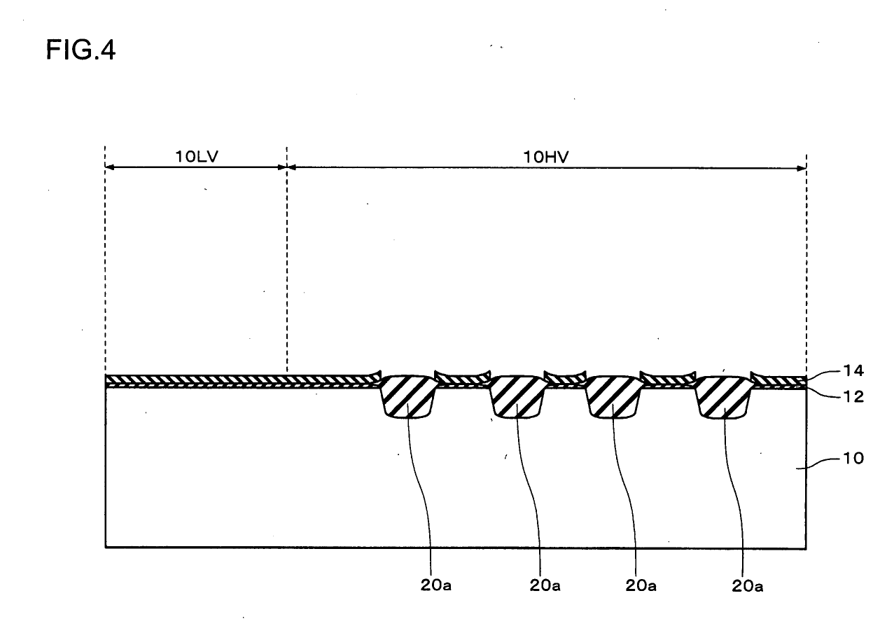

(3) Next, as shown in FIG. 4, using the silicon nitride layer 14 as the mask, a semi-recessed LOCOS layer 20a are formed by the selective thermal oxidation method.

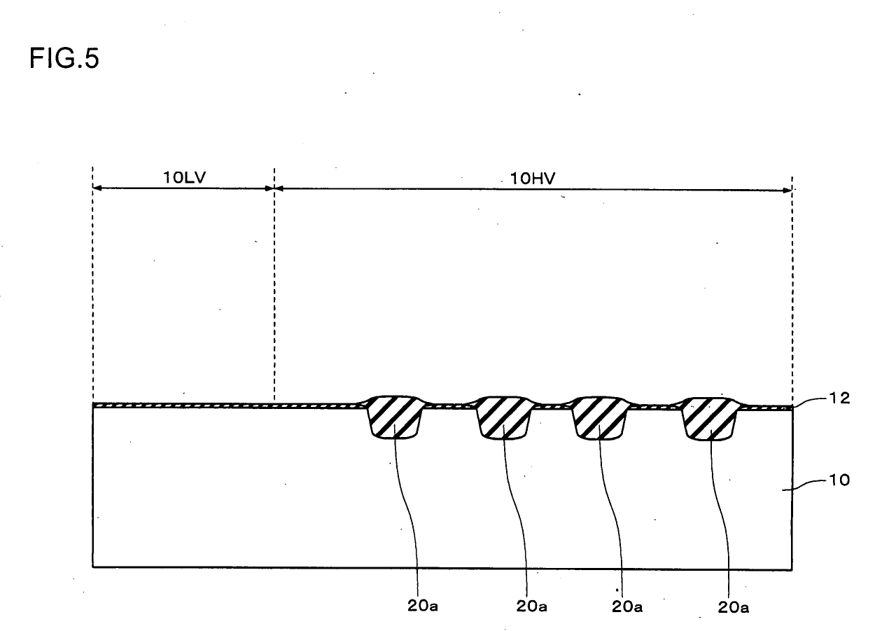

(4) Next, as shown in FIG. 5, the silicon nitride layer 14 is removed. For example, the silicon nitride layer 14 can be removed by a thermal phosphoric acid.

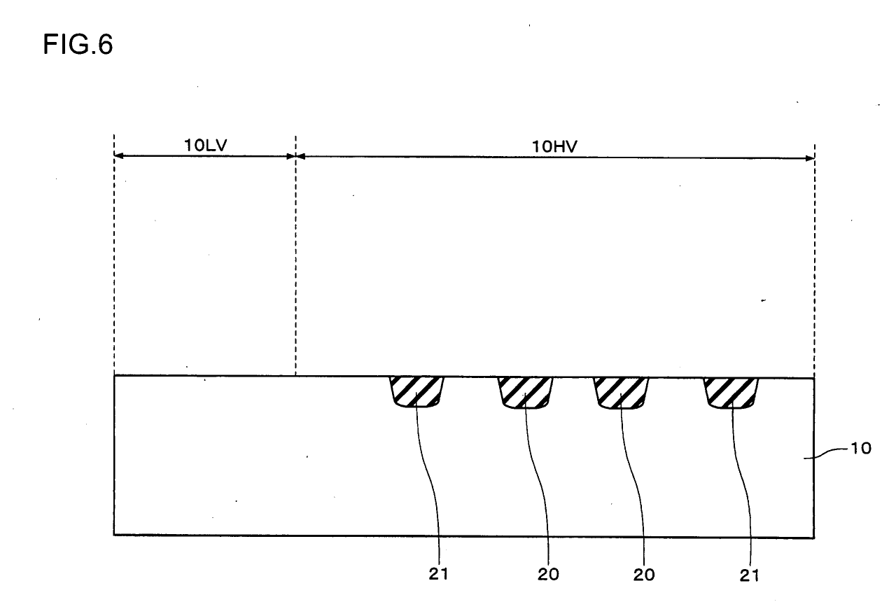

(5) Next, as shown in FIG. 6, the offset insulating layer 20 and the isolation insulating layer 21 are formed by removing the upper surface of the LOCOS layer 20a so that the upper surface of the LOCOS layer 20a is nearly as high as the surface of the semiconductor substrate 10. The upper surface of the LOCOS layer 20a is removed by the known etching technique, and can be etched by either anisotropic etching or isotropic etching. In particular, when they are removed by isotropic wet etching, it is preferable because there are following advantages. For example, when the upper surface of the LOCOS layer 20a is removed by anisotropic dry etching or the like, sharp level differences are formed on the surface of the LOCOS layer 20a having the removed portions and there may be some concerns that films remain when the CMP is carried out. On the other hand, when isotropic etching is used, the upper surface of the LOCOS layers 20a having the removed portions have smooth shapes (shape having curved surface), concerns that films remain when the CMP is carried out are eliminated, and then the upper surfaces of the LOCOS layers 20a can be more flattened. When carried out by isotropic etching, it is preferable to carry out wet etching using diluted hydrofluoric acid or the like.

This etching of the LOCOS layers 20a is carried out so that the upper surfaces of the LOCOS layers 20a after etching are nearly as high as the surface of the semiconductor substrate 10. Here, being nearly as high as the surface of the semiconductor substrate 10 means that there is a difference of elevation in an extent that can be corrected in a CMP process carried out in a process described later. Moreover, before a sacrifice oxide film 18 described later is formed, light etching is carried out so that the surface of the semiconductor substrate 10 is clean, however, a combination of etching the upper surfaces of the LOCOS layers 20a in (5) and light etching process can be carried out.

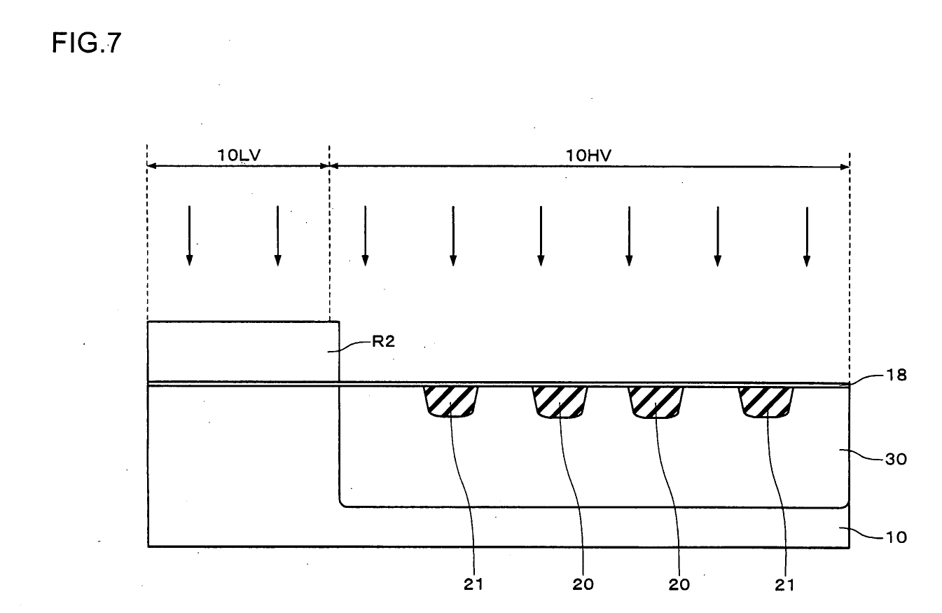

(6) Next, as shown in FIG. 7, the N-type well 30 is formed in the high breakdown voltage transistor region 10HV. First, the sacrifice oxide film 18 is formed on the entire surface of the semiconductor substrate 10. For example, a silicon oxide film is formed as the sacrifice oxide film 18. Next, a resist layer R2 having a predetermined pattern is formed, using the resist layer R2 as the mask, and then a N-type impurities such as phosphorous or arsenic are injected into the semiconductor substrate 10 once or several times. Next, the resist layer R2 is removed by ashing, and the injected N-type impurities are thermally diffused by heat treatment. This allows the N-type well 30 to be formed in the semiconductor substrate 10.

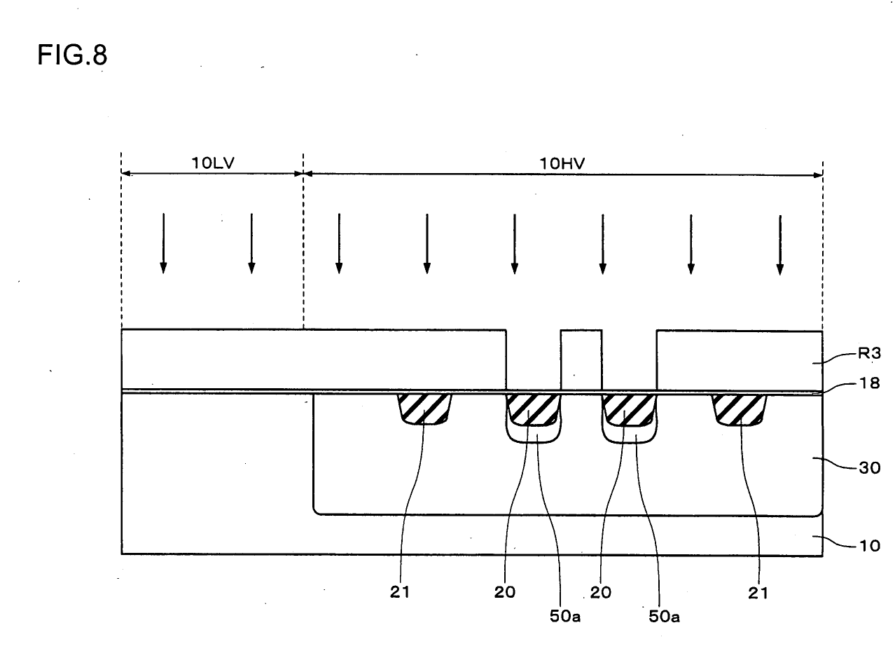

(7) Next, a low concentration impurity layer in the offset region for the electric field relaxation of the high breakdown voltage transistor is formed. First, as shown in FIG. 8, a resist layer R3 having a predetermined pattern is formed. Using this resist layer R3 as the mask, an impurity layer 50a is formed by introducing a P-type impurity into the semiconductor substrate 10. After that, the resist layer R3 is removed.

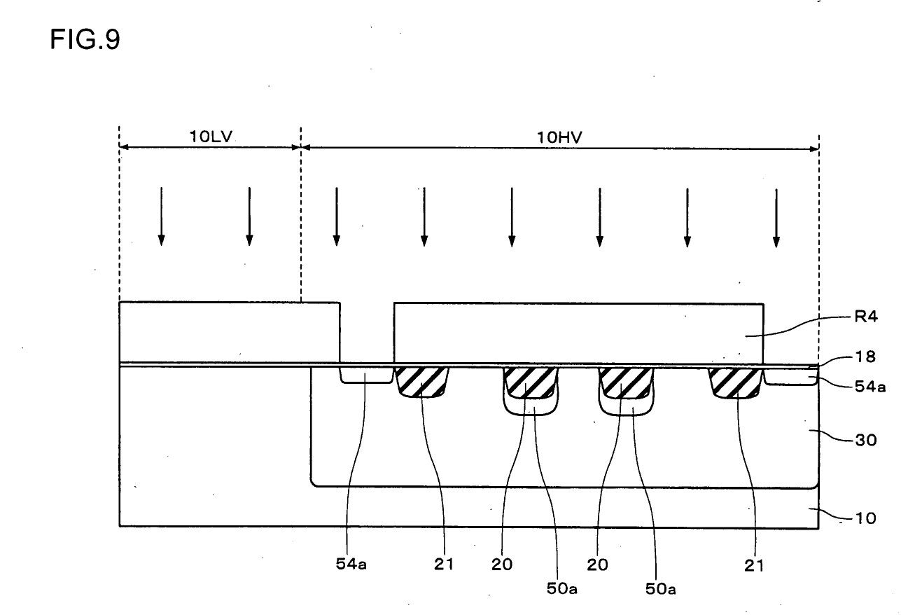

(8) Next, an impurity for a low concentration impurity layer 54 (refer to FIG. 1) provided below the guard ring region 56 is introduced into the semiconductor substrate 10. First, as shown in FIG. 9, a resist layer R4 having a predetermined pattern is formed. Using this resist layer R4 as the mask, an impurity layers 54a are formed by introducing the N-type impurity into the semiconductor substrate 10.

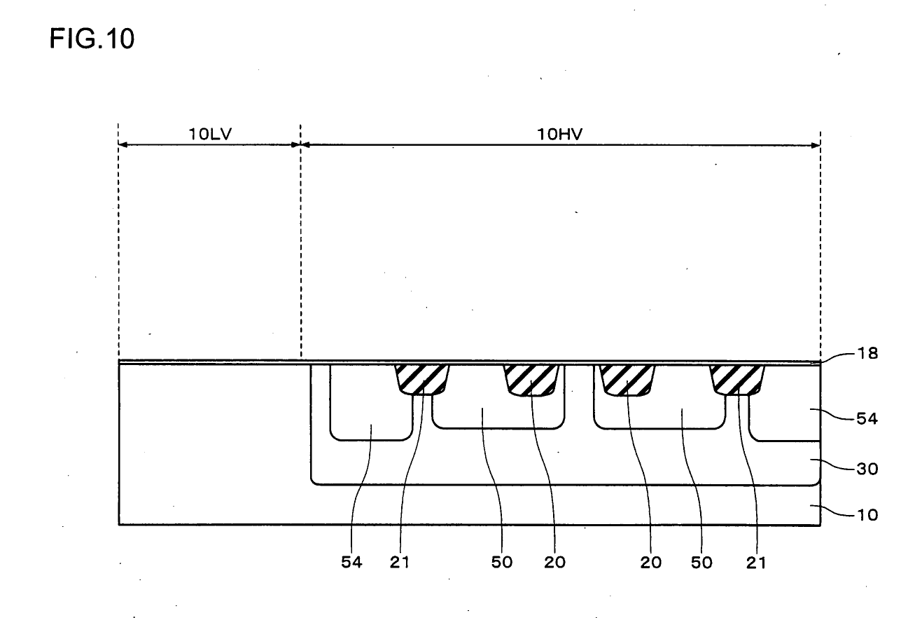

(9) Next, as shown in FIG. 10, the impurity layers 50a and 54a are diffused by carrying out heat treatment by the known technique, then the P-type low concentration impurity layer 50 which becomes the offset region for the high breakdown voltage transistor 100 and the N-type low concentration impurity layer 54 which becomes the offset region for the guard ring region 56 are formed. After that, the sacrifice oxide film 18 is removed by the known method.

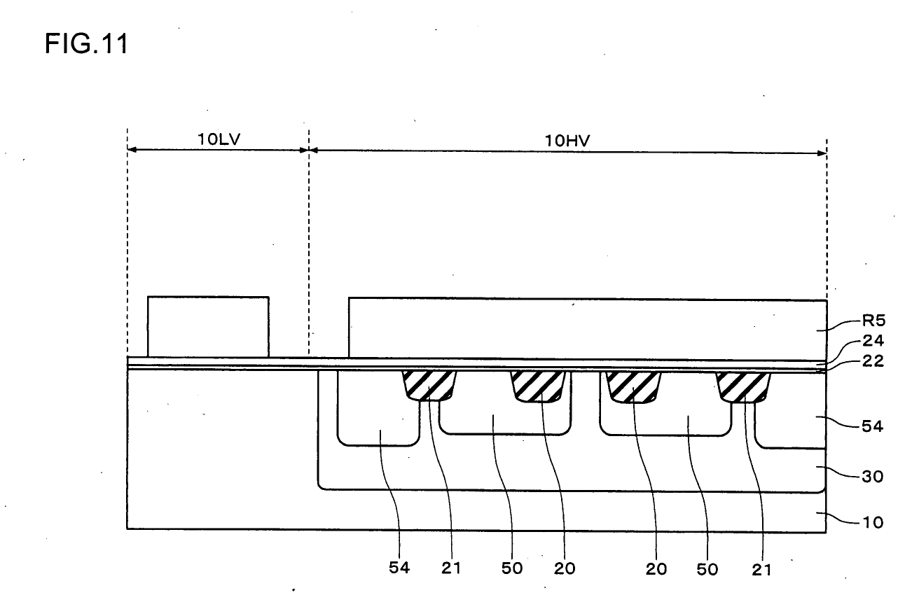

(10) Next, in order to define the low voltage driving transistor forming region 10LV, the trench insulating layer 28 is formed (refer to FIG. 1). First, as shown in FIG. 11, a pad oxide film 22 is formed on the entire surface of the semiconductor substrate 10. Next, a stopper insulating layer 24 is formed above the pad oxide film 22. As the stopper insulating layer 24, a silicon nitride layer can be formed by, for example, the CVD method. Next, a resist layer R5 is formed on the stopper insulating layer 24 as the mask layer having the opening to a region where a second element isolation region 210 is formed.

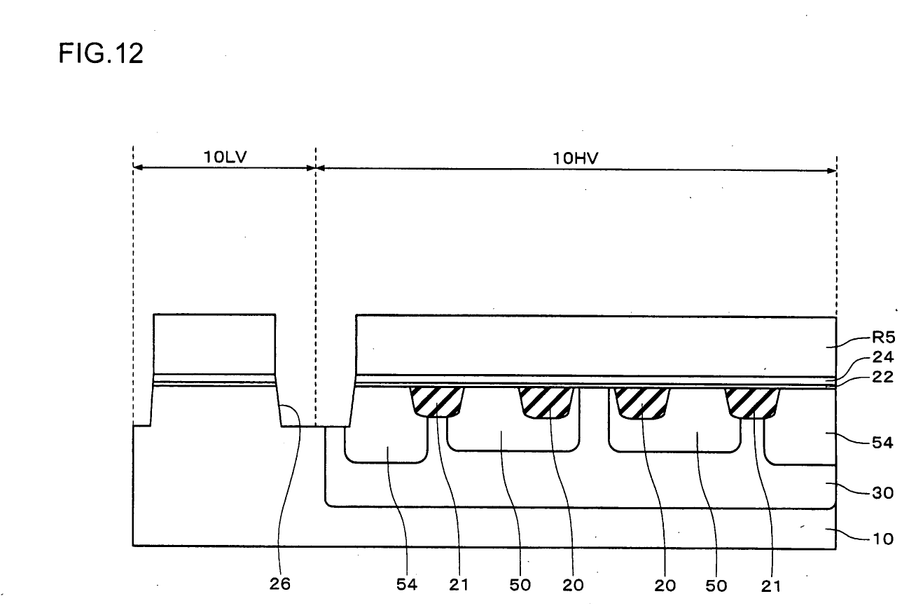

(11) Next, as shown in FIG. 12, using the resist layer R5 as the mask, the stopper insulating layer 24, the pad oxide film 22 and the semiconductor substrate 10 are etched by the known etching technique. This allows a trench 26 to be formed.

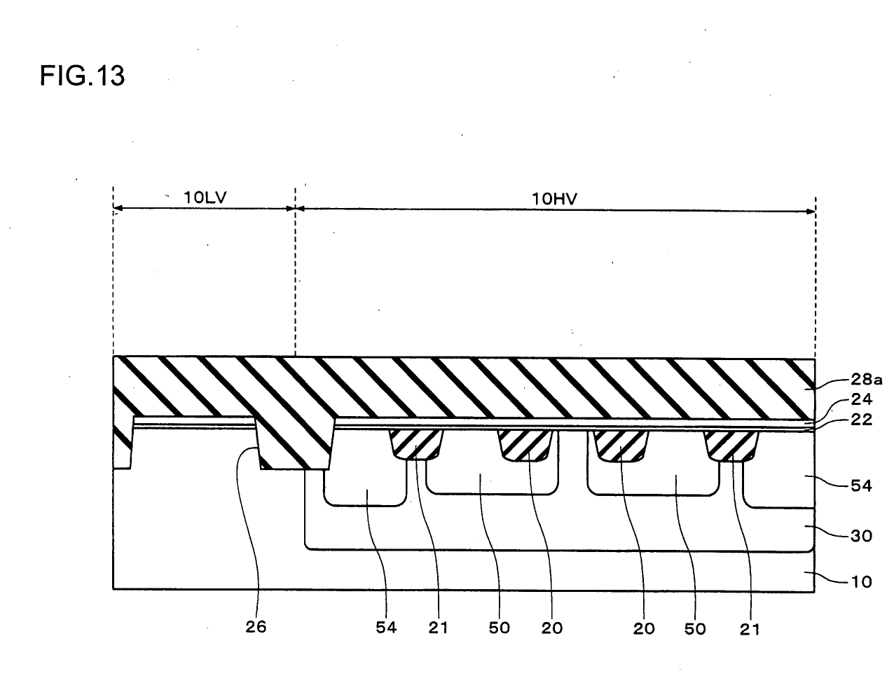

(12) Next, a trench oxidation film (not shown) is formed on the surface of the trench 26. A manufacturing method of the trench oxidation film is, for example, carried out by the thermal oxidation method. Next, as shown in FIG. 13, an insulating layer 28a is deposited on the entire surface so that the trench 26 is embedded. As a forming method of the insulating layer 28a, for example, the CVD method, a high density plasma CVD method or the like are used.

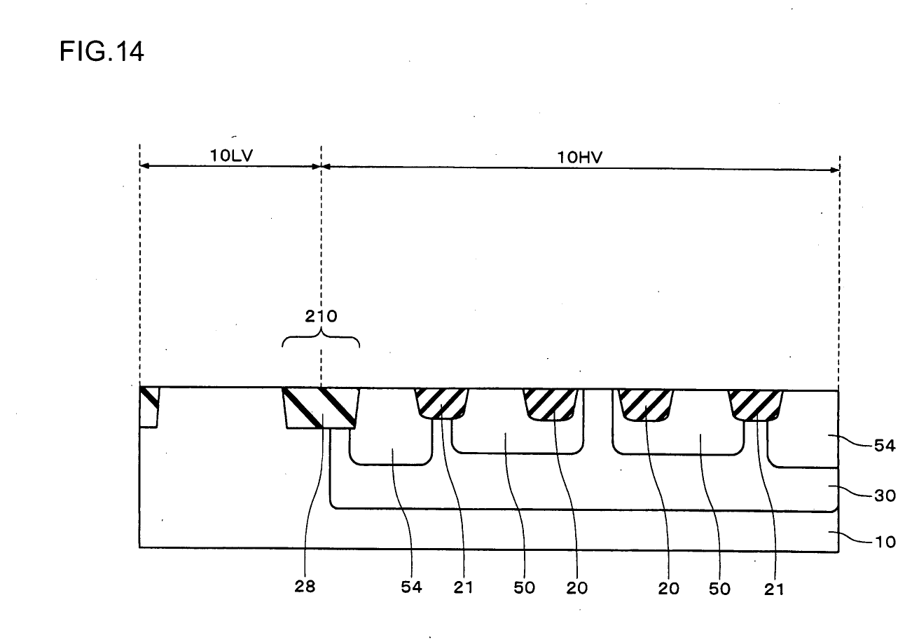

(13) Next, the deposited insulating layer 28a is removed until it becomes nearly as high as the surface of the semiconductor substrate 10. As shown in FIG. 14, this allows the trench insulating layer 28 to be formed. The etching of the insulating layer 28a is carried out by, for example, the CMP method. In addition, before carrying out this CMP method, in order to eliminate difference of elevation on the surface of the insulating layer 28a, a flattening insulating layer such as a SOG layer can be formed if necessary.

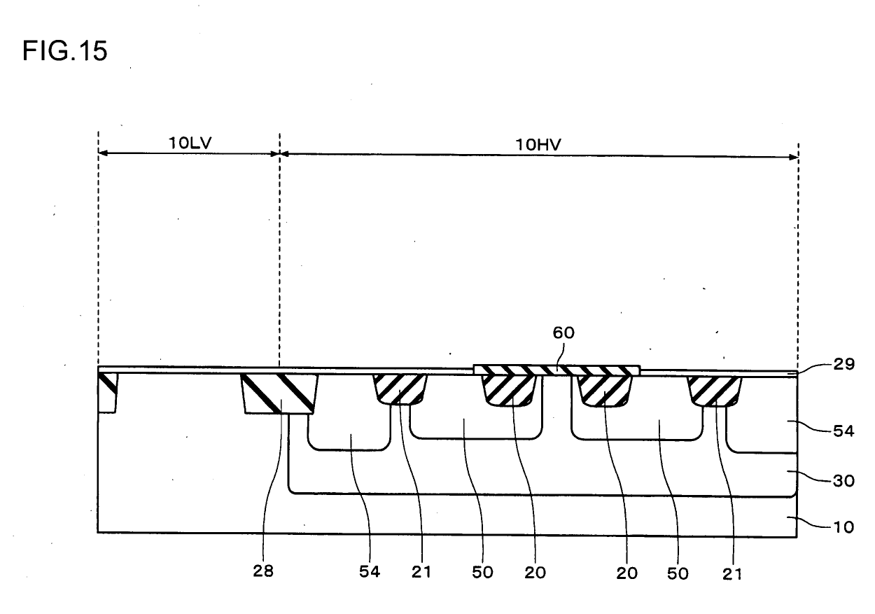

(14) Next, as shown in FIG. 15, a protective film 29 is formed so that at least other than a region where the gate insulating layer 60 of the high breakdown voltage transistor 100 is formed is covered. As the protective film 29, for example, the silicon nitride layer can be used. To form the protective film 29, first, the silicon nitride layer (not shown) is formed on the entire surface of the semiconductor substrate 10. Next, a resist layer (not shown) is formed having the opening to the region where the gate insulating film 60 is formed in a later process, using this resist layer as the mask, the protective film 29 is formed by patterning the silicon nitride layer.

Next, as shown in FIG. 15, the gate insulating layer 60 is formed in the high breakdown voltage transistor region 10HV. The gate insulating layer 60 can be formed by the selective thermal oxidation method. The film thickness of the gate insulating layer 60 can be, for example, 1600 angstrom. Next, the remaining silicon nitride layer 26 is removed. Additionally, in the process (14), channel doping may be carried out after the protective film 29 is formed.

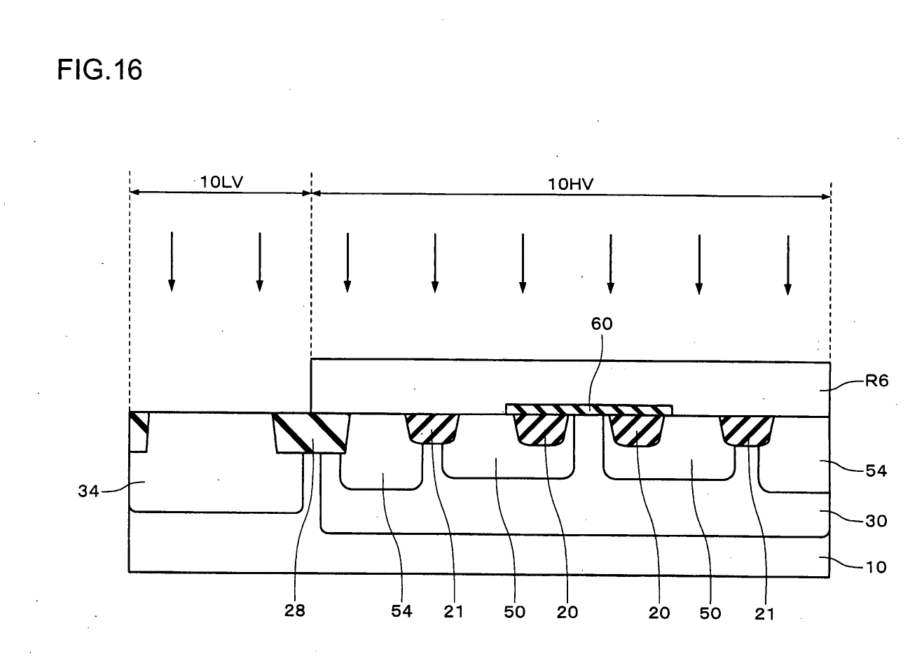

(15) Next, as shown in FIG. 16, a well in the low voltage driving transistor region 10LV is formed. First, the resist layer R6 is formed so as to cover a region other than the low voltage driving transistor forming region 10LV. Next, using this resist layer R6 as the mask, the N-type well 34 is formed by injecting the N-type impurity such as phosphorous or arsenic once or several times. Next, the resist layer R6 is removed by, for example, ashing.

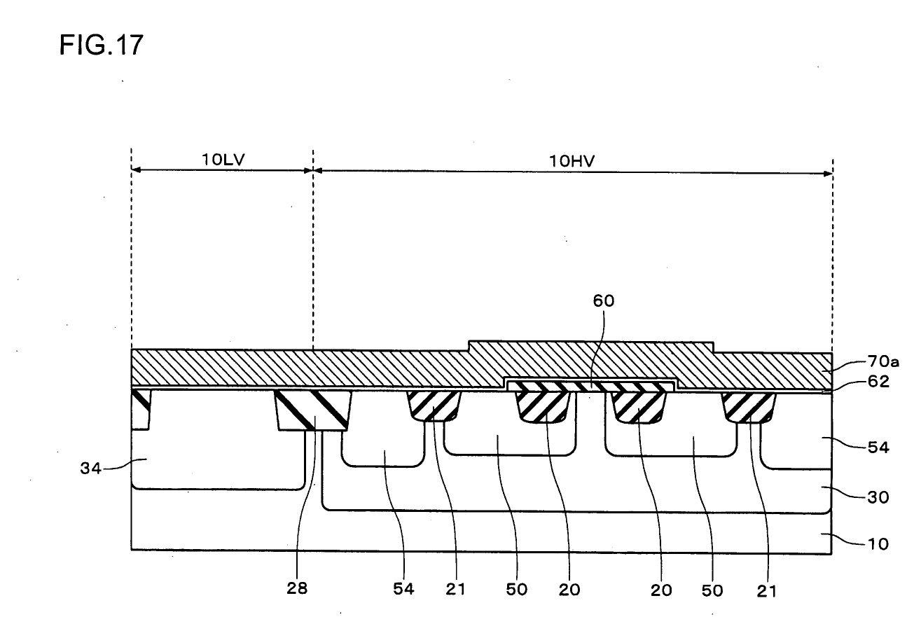

(16) Next, as shown in FIG. 17, the gate insulating layer 62 for the low voltage driving transistor 200 is formed. The gate insulating layer 62 is formed by, for example, the thermal oxidation method. The film thickness of the gate insulating layer 62 can be, for example, 45 angstrom. Furthermore, the gate insulating layer 62 is formed even in the high breakdown voltage transistor region 10HV.

Next, as shown in FIG. 17, a conductive layer 70a is formed on the entire surface of the high breakdown voltage transistor region 10HV and the low voltage driving transistor region 10LV. As the conductive layer 70a, for example, a poly-silicon layer is formed.

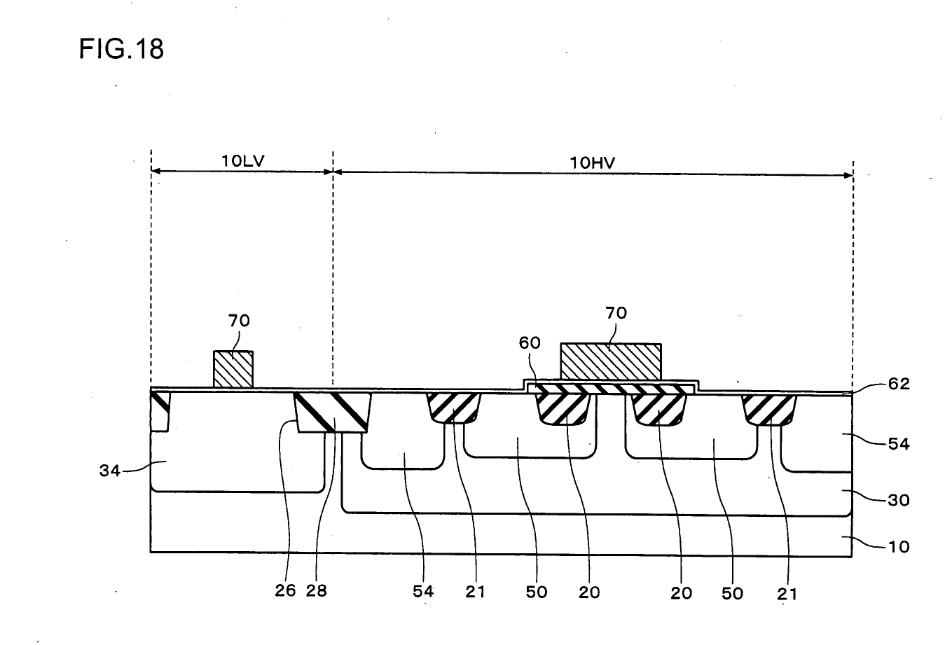

(17) Next, as shown in FIG. 18, the gate electrode 70 is formed by patterning the conductive layer 70a. First, the resist layer (not shown) having a predetermined pattern is formed on the conductive layer 70a. Using this resist layer as the mask, the gate electrode 70 is formed by patterning the poly-silicon layer.

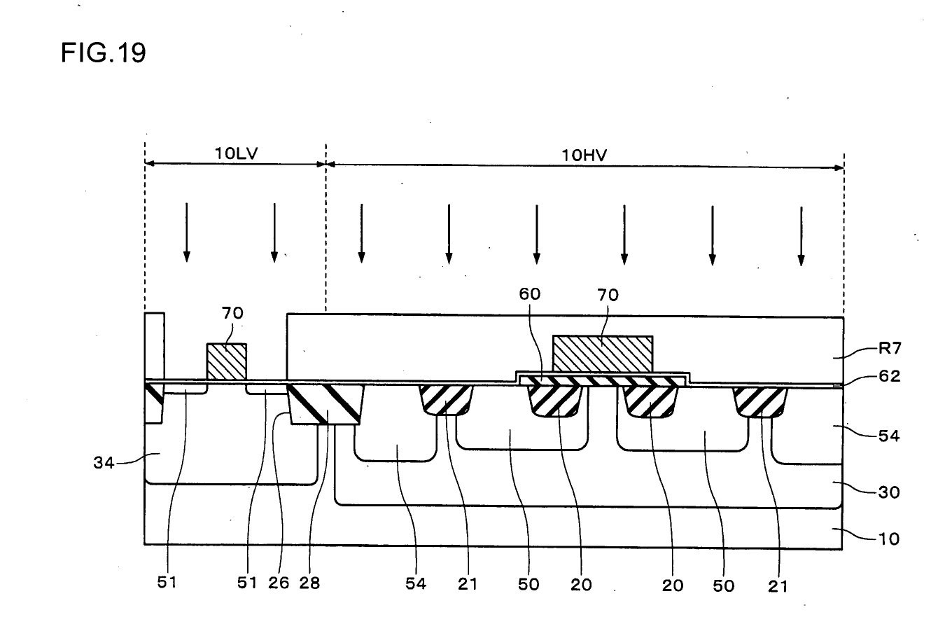

(18) Next, as shown in FIG. 19, in the low voltage driving transistor region 10LV, a low concentration impurity layer 51 for the low voltage driving transistor 200 is formed. To form the low concentration impurity layer 51, first, a resist layer R7 having a predetermined pattern is formed. Next, using the resist layer R7 as the mask, the low concentration impurity layer 51 can be formed by injecting the P-type impurity.

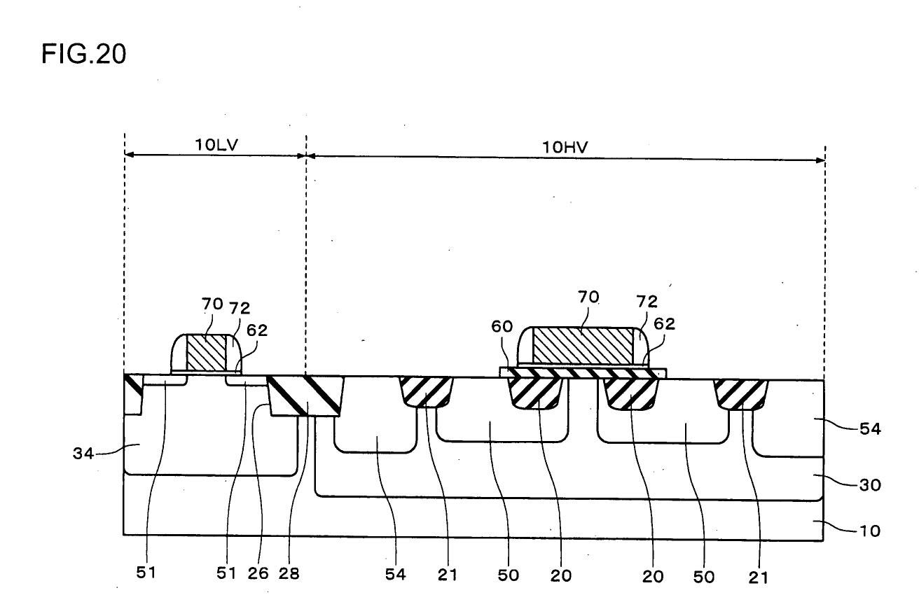

(19) Next, as shown in FIG. 20, the sidewall insulating layers 72 are formed on the side surface of the gate electrode 70. To form the sidewall insulating layers 72, first, the insulating layer (not shown) is formed on the entire surface. Next, the sidewall insulating layers 72 are formed by carrying out anisotropic etching on this insulating layer.

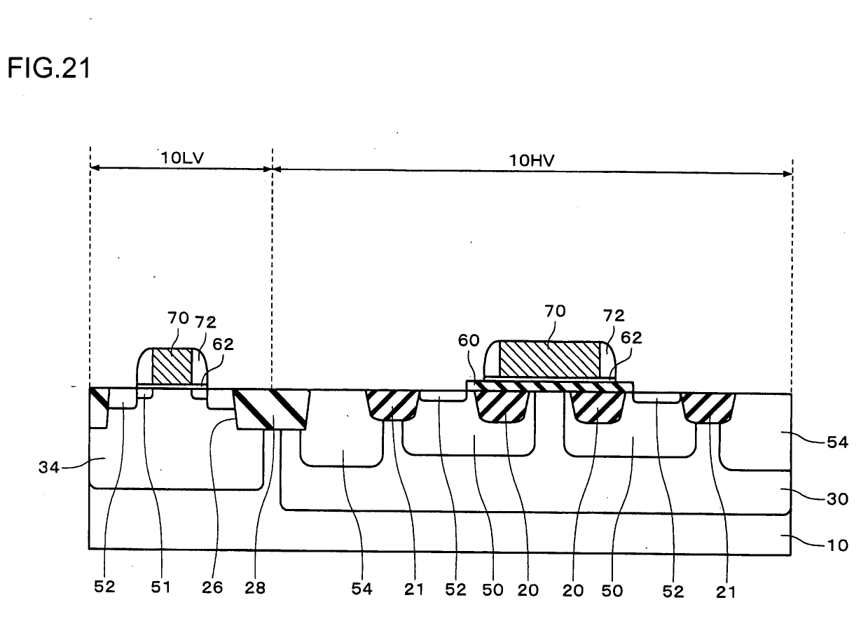

(20) Next, as shown in FIG. 21, by introducing the P-type impurity into predetermined regions in the high breakdown voltage transistor region 10HV and the low voltage driving transistor region 10LV, as shown in FIG. 1, the P-type high concentration impurity layer 52 which becomes the source/drain region is formed.

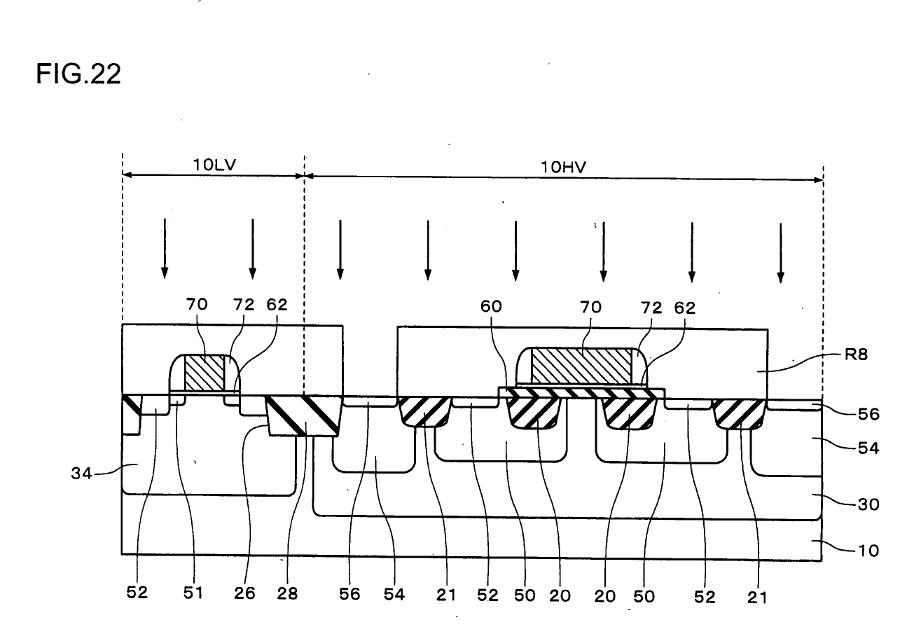

(21) Next, as shown in FIG. 22, the guard ring region 56 playing a role of the element isolation for the high breakdown voltage transistor 100 is formed. First, a resist layer R8 is formed so as to cover areas other than a forming region of the guard ring region 56. Next, using the resist layer R8 as the mask, the guard ring region 56 is formed by introducing an N-type impurity layer into the semiconductor substrate. Furthermore, the guard ring region 56 can be formed by the same process of forming an N-type source and a drain region for a counter conductive transistor (not shown) in the high breakdown voltage transistor 100.

(22) Next, the semiconductor device shown in FIG. 1 can be manufactured by the known technique by forming a plurality of interlayer insulating layers 120 and 130, wiring layers 122 and 132, and contact layers 124 and 134 as referred to FIG. 1.

According to the manufacturing method of the semiconductor device of the present embodiment, the offset insulating layer 20 for the electric field relaxation of the high breakdown voltage transistor 100 is formed by etching until the upper surface thereof becomes nearly as high as the surface of the semiconductor substrate 10 after the LOCOS layer 20a is formed. The LOCOS layer 20a is formed by using the selective thermal oxidation method, therefore, the LOCOS layer 20a is formed to rise above the surface of the semiconductor substrate 10. When the CMP process necessary for formation of the trench insulating layer with a difference of elevation on the surface of the semiconductor substrate 10 is carried out in this way, difference in etching rate occurs and then the CMP (flattening) cannot be carried out favorably. However, according to the manufacturing method of the semiconductor device of the present embodiment, the upper surface of the LOCOS layer 20a is etched so as to be nearly as high as the surface of the semiconductor substrate 10. For this reason, the CMP process carried out when the trench insulating layer 28 is formed can be carried out in a state where a difference of elevation on the surface of the semiconductor substrate 10 is decreased. As a result, even for a semiconductor device using both of a LOCOS method and the STI method, the semiconductor device with high reliability can be manufactured.

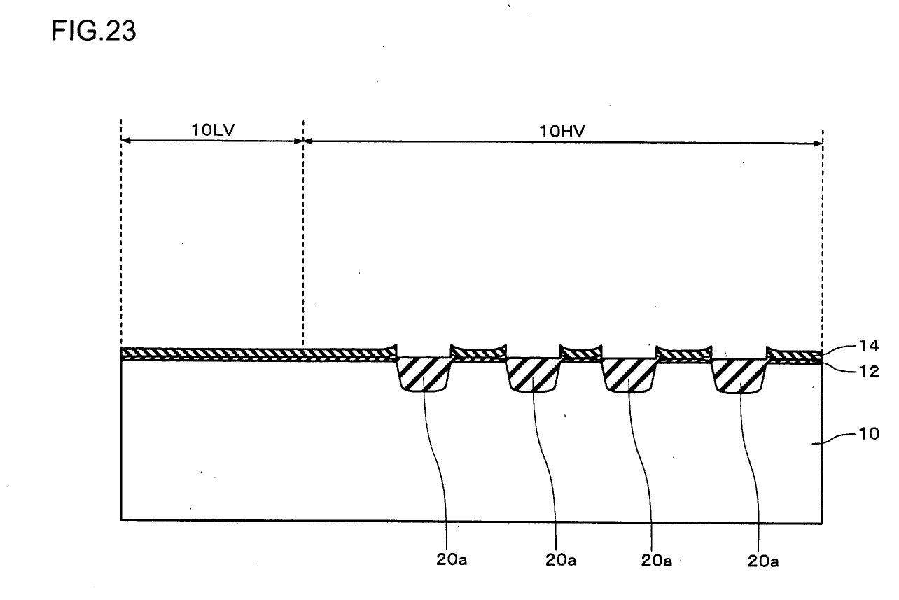

Next, a modification of the manufacturing method of the semiconductor device according to the present embodiment will be described with reference to FIG. 23.

The present modification differs from the above described embodiment in a method of etching at least a part of the upper surface of the LOCOS layer 20a. In the description below, processes differing from the above described embodiment will be described.

First, in the same way as the above described embodiment, the LOCOS layer 20a is formed by carrying out the processes (1) through (3). Next, as shown in FIG. 23, a part of the upper surface of the LOCOS layer 20a is etched without removing the silicon nitride layer 14 which is the oxidation resistant film. In this case, the upper surface of the LOCOS layer 20a on the area not covered with the silicon nitride layer 14 is etched so as to be nearly as high as the surface of the semiconductor substrate 10. This etching can be carried out in the same way as the process (5) in the above described embodiment.

Next, the semiconductor device according to the present modification can be manufactured by removing the silicon nitride layer 14 and carrying out the processes (6) through (22) in the above described embodiment in the same way.

According to the manufacturing method of the semiconductor device of the present modification, the same effects as those of the manufacturing method of the semiconductor device according to the above described embodiment can be obtained, and at least a part of the upper surface of the LOCOS layer 20a is etched so as to be nearly as high as the surface of the semiconductor substrate 10, thereby a difference of elevation between the surface of the LOCOS layer 20a and that of the semiconductor substrate 10 can be decreased. Accordingly, the CMP can be acceptably carried out when the trench insulating layer 28 is formed. As a result, even in the manufacturing method of the semiconductor device using a combination of the LOCOS method and the STI method, the semiconductor device with high reliability can be manufactured.

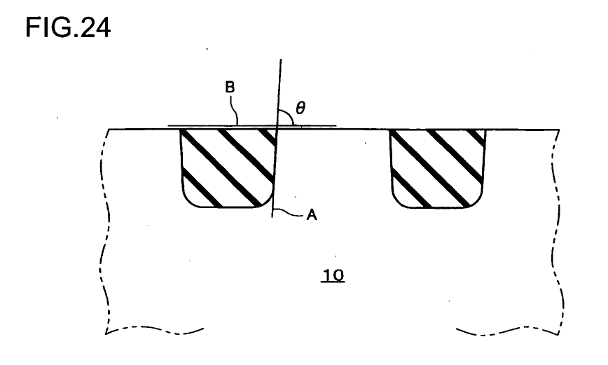

Furthermore, in the semiconductor device obtained according to this aspect, the upper end portion of the LOCOS layer 20a is covered with the silicon nitride layer 14, therefore, is not etched. This advantage will be described with reference to FIG. 24. FIG. 24 shows only an enlarged upper end portion of the LOCOS layer in an embodiment when the upper end portion of the LOCOS layer is etched. If a portion having bird's beak shape in the LOCOS layer is removed in case that the upper end portion of the LOCOS layer is etched, as shown in FIG. 24, an angle θ formed between a straight line A along the upper end portion of the LOCOS layer and a straight line B along the surface of the semiconductor substrate 10 may exceed 30°. When the gate insulating layer with thick film is formed on the LOCOS layer with a shape of an angle formed between the straight line A and the straight line B exceeding 30°, the thinning may occur at the upper end portion of the LOCOS layer. In other words, the gate insulating layer having uniform film thickness cannot be formed, and then, reliability of the semiconductor device may be impaired. However, according to the present modification, the upper end portion of the LOCOS layer 20a is covered with the nitride film, and is not etched, thereby the above described problem can be avoided.

In addition, the present invention is not limited to the above described embodiment, and can be modified. For example, in the present embodiment, a case when a semi-recessed LOCOS method is used as the forming method of the offset insulating layer 20 has been explained, however, the offset insulating layer 20 may be formed by the LOCOS method.

Furthermore, an example that the element isolation of the high breakdown voltage transistor is carried out by the guard ring has been explained, however, this may be carried out by the trench insulating layer or the LOCOS layer. Moreover, in the semiconductor device of the present embodiment, a case when one high breakdown voltage transistor and one low voltage driving transistor are formed on the same semiconductor layer is explained, however, the present invention is not limited to this case, and a plurality of various kinds of transistors may be formed on the same semiconductor layer.

1. A semiconductor device provided with a high breakdown voltage transistor and a low voltage driving transistor on a same semiconductor layer, comprising:
the semiconductor layer,
an offset insulating layer comprising a LOCOS layer or a semi-recessed LOCOS layer for an electric field relaxation of the high breakdown voltage transistor provided on the semiconductor layer; and
a trench insulating layer for defining a forming region of the low voltage driving transistor provided on the semiconductor layer,
wherein at least a part of an upper surface of the offset insulating layer is nearly as high as a surface of the semiconductor layer.

2. The semiconductor device according to claim 1, wherein an entire surface of the upper surface of the offset insulating layer is nearly as high as the surface of the semiconductor layer.

3. The semiconductor device according to claim 1 or 2, wherein the semiconductor layer is provided with a guard ring surrounding a forming region of the high breakdown voltage transistor.

4. The semiconductor device according to claims 1 or 2, wherein the semiconductor layer is provided with the LOCOS layer or the semi-recessed LOCOS layer as an element isolation for defining the forming region of the high breakdown voltage transistor.

5. The semiconductor device according to claims 1 or 2, wherein the semiconductor layer is provided with a trench insulating layer as an element isolation for defining the forming region of the high breakdown voltage transistor.

6. A manufacturing method of a semiconductor device comprising:
(a) forming a LOCOS layer or a semi-recessed LOCOS layer on a semiconductor layer;
(b) etching at least a part of an upper surface of the LOCOS layer or the semi-recessed LOCOS layer; and
(c) forming a trench insulating layer on the semiconductor layer.

7. A manufacturing method of a semiconductor device comprising:
(a) forming a LOCOS layer or a semi-recessed LOCOS layer on a semiconductor layer for an electric field relaxation of a high breakdown voltage transistor;
(b) removing at least a part of an upper surface of the LOCOS layer or the semi-recessed LOCOS layer, and forming an offset insulating layer; and
(c) forming a trench insulating layer on the semiconductor layer for defining a forming region of a low voltage driving transistor.

8. The manufacturing method of a semiconductor device according to claim 6 or 7, wherein the LOCOS layer forming step comprises:
forming an oxidation resistant film on the semiconductor layer;
removing the oxidation resistant film in the forming region of the LOCOS layer or the semi-recessed LOCOS layer; and
forming the LOCOS layer or the semi-recessed LOCOS layer by performing a thermal oxidation by using the oxidation resistant film as a mask,
wherein, the etching step includes etching the upper surface of the LOCOS layer or the semi-recessed LOCOS layer by using the remaining oxidation resistant film as the mask.

9. The manufacturing method of a semiconductor device according to claim 6 or 7, wherein the LOCOS layer forming step comprises:
forming an oxidation resistant film on the semiconductor layer;
removing the oxidation resistant film in the forming region of the LOCOS layer or the semi-recessed LOCOS layer; and
forming the LOCOS layer or the semi-recessed LOCOS layer by performing a thermal oxidation by using the oxidation resistant film as a mask,
and further, removing the remaining oxidation resistant film before the (b).

10. The manufacturing method of a semiconductor device according to claims 6 or 7, wherein the trench insulating forming step comprises:
forming a trench on the semiconductor layer,
forming an insulating layer above the semiconductor layer where the trench is formed, and
flattening the insulating layer by a CMP method.

11. The manufacturing method of a semiconductor device according to claims 6 or 7, wherein the etching is carried out by isotropic etching.

12. The semiconductor device according to claim 3, wherein the semiconductor layer is provided with the LOCOS layer or the semi-recessed LOCOS layer as an element isolation for defining the forming region of the high breakdown voltage transistor.

13. The semiconductor device according to claim 3, wherein the semiconductor layer is provided with a trench insulating layer as an element isolation for defining the forming region of the high breakdown voltage transistor.

14. The manufacturing method of a semiconductor device according to claim 8, wherein the trench insulating forming step comprises:
forming a trench on the semiconductor layer,
forming an insulating layer above the semiconductor layer where the trench is formed, and
flattening the insulating layer by a CMP method.

15. The manufacturing method of a semiconductor device according to claim 9, wherein the trench insulating forming step comprises:
forming a trench on the semiconductor layer,
forming an insulating layer above the semiconductor layer where the trench is formed, and
flattening the insulating layer by a CMP method.

16. The manufacturing method of a semiconductor device according to claim 8, wherein the etching step is carried out by isotropic etching.

17. The manufacturing method of a semiconductor device according to claim 9, wherein the etching step is carried out by isotropic etching.

18. The manufacturing method of a semiconductor device according to claim 10, wherein the etching step is carried out by isotropic etching.

19. The method of claim 6, wherein the etching step is performed such that an upper surface of the LOCOS layer or the semi-recessed LOCOS layer is nearly as high as an upper surface of said semiconductor layer.

20. The method of claim 6, wherein said etching step is performed by isotropic wet etching.

21. The method of claim 6, wherein an upper surface of the LOCOS layer is etched to be nearly as high as a surface of the semiconductor layer.

22. The method of claim 6, wherein an upper surface of the LOCOS layer is removed to be to be nearly as high as a surface of the semiconductor layer.

23. A semiconductor device provided with a plurality of kinds of transistors are formed on a same semiconductor layer, comprising:
the semiconductor layer,
an offset insulating layer comprising a LOCOS layer or a semi-recessed LOCOS layer for an electric field relaxation of the high breakdown voltage transistor provided on the semiconductor layer; and
a trench insulating layer for defining a forming region of the low voltage driving transistor provided on the semiconductor layer,
wherein at least a part of an upper surface of the offset insulating layer is nearly as high as a surface of the semiconductor layer.
